(19) United States
(12) Patent Application Publication
(10) Pub. No.: US 2009/0263928 A1
(43) Pub. Date: Oct. 22, 2009

(54) METHOD FOR MAKING A SELECTIVE EMITTER OF A SOLAR CELL

(75) Inventor: Yu-Chu Tseng, Jungli City (TW)

Correspondence Address: VOLPE AND KOENIG, P.C., UNITED PLAZA, SUITE 1600, 30 SOUTH 17TH STREET, PHILADELPHIA, PA, 19103, US

(73) Assignee: MOSEL VITELIC INC., Hsinchu (TW)

(21) Appl. No.: 12/180,230

(22) Filed: Jul. 25, 2008

(30) Foreign Application Priority Data
Apr. 16, 2008 (TW) 097113870

(51) Int. Cl. H01L 31/00

(52) U.S. Cl. 438/73; 257/E31.001

(57) ABSTRACT

A method for manufacturing a selective emitter of a solar cell is provided. The method includes steps of providing a substrate; forming an emitter layer on the substrate, wherein the emitter layer has a heavily doped portion located on a top thereof and a relatively lightly doped portion located at a bottom thereof; forming a patterned mask layer on the emitter layer; and performing a wet etching for exposing a region of the relatively lightly doped portion which is not covered by the patterned mask layer.

### FIELD OF THE INVENTION

The present invention relates to a solar cell, and more particularly to a solar cell with a selective emitter.

### BACKGROUND OF THE INVENTION

The solar cells with selective emitters have prevailed in the industry. The so-called selective emitter is selecting different doping densities on an N-type silicon layer, to make a heavily doped N-type silicon underneath the grid lines and a lightly doped N-type silicon in other areas (active region). The main reason for adopting the selective emitter is because such a structure has an improved open-circuit voltage (V_{OC}), short-circuit current (I_{SC}) and fill factor (F.F.) for a solar cell so that the sunlight-to-energy efficiency is increased thereby.

First of all, the advantage of forming lightly doped N-type silicon in an active region is to reduce carrier recombination, so as to reduce the reverse saturation current and increase the V_{OC}. In addition, the closer to the surface of a solar cell, the higher opportunity a carrier is produced. And the closer to a diffused junction, the higher carrier collection rate is. Therefore, a higher carrier collection rate can be achieved in the lightly doped region and result in a higher I_{SC}.

Secondly, for the heavily doped N-type silicon underneath the grid lines, a contact resistance between the silicon and the grid lines is reduced, thereby reducing the series resistance of the cell and increasing the fill factor. In addition, a high-low junction between a heavily doped area and a lightly doped area can increase the collection rate. Besides, heavy doping can also avoid the electrode metal penetrating toward the junction, thereby reducing the possibility of inducing the electrode metal within a bandgap to an impurity energy level.

The advantages respectively from heavy doping and light doping are so obvious and complement each other. Therefore, a variety of solar cell structures as well as their manufacturing methods looking for forming lightly doped N-type silicon at the active region while forming heavily doped N-type silicon around the grid metal lines have been developed.

Please refer to FIG. 1, which is a schematic diagram showing the procedure of making a selective emitter of a solar cell in the prior art. As shown in FIG. 1, an N-type silicon layer 2 is formed on top of a P-type silicon substrate 1. The N-type silicon 2 is essentially composed of two portions, namely a lightly doped portion and a heavily doped portion. Since most of the current habitual practices are dividing the N-type silicon layer into several portions of different doping concentration rather than the lightly and heavily doped portions only, FIG. 1 fails to disclose it comprehensively. Therefore, the N-type silicon layer 2 is made from the P-type silicon substrate 1. Firstly, a first N-type silicon layer 21 is formed. Then, a second N-type silicon layer 22 and a third N-type silicon layer 23 are formed in sequence. With respect to the relative doping concentration of the three layers, the first N-type silicon layer 21 has the lowest density, the second N-type silicon layer 22 has more, and the third N-type silicon layer 23 has the highest density.

As mentioned hereinbefore, the heavily doped N-type silicon is for coupling to the grid metal lines. So the third N-type silicon layer 23 of the highest doping concentration is solely reserved for taking on the portion of the grid metal lines (not shown). The other portion is reserved for serving as active regions. And indeed the active regions require the lightly doped N-type silicon only. Therefore the middle area in FIG. 1 shows an area in which both the second N-type silicon layer 22 and the third N-type silicon layer 23 of the active region are removed. Currently the method of plasma bombardment is adopted for the removal. Then, pleases refer to the lower part of FIG. 1, a layer of silicon nitride 3 is formed on the entire N-type silicon layer 2. And finally a grid metal line 4 is formed on top of the third N-type silicon layer 23. Up to now, a solar cell with a selective emitter has been completed.

The abovementioned production method is often criticized for its extremely high price. It is not easy to control the etching process either, for usually under etching or over etching. However, the method is essentially rather convenient. The method of forming N-type silicon layers of different doping densities in sequence still has a good potential, provided that an effective and also low-cost way of removing the extra heavily doped portions can be found.

### SUMMARY OF THE INVENTION

To achieve the abovementioned object, the present invention provides a method for manufacturing a selective emitter of a solar cell. The method includes the following steps: providing a silicon substrate; forming an emitter layer on the silicon substrate, wherein the emitter layer has a heavily doped portion located on a top thereof and a relatively lightly doped portion located at a bottom thereof; forming a mask layer being patterned on the emitter layer; and performing a wet etching for exposing the lightly doped portion which is not covered by the mask layer.

In accordance with the same aspect of the present invention, the method further includes the following steps: removing the mask layer; forming a nitric layer on a first surface of the lightly doped portion of the emitter layer; and forming a metal grid on a second surface of the heavily doped portion of the emitter layer.

In accordance with the abovementioned method, the mask layer is made of a wax.

In accordance with the abovementioned method, the silicon substrate and the emitter layer form a P-N junction.

In accordance with the abovementioned method, the mask layer is defined by a photolithography.

In accordance with the abovementioned method, the mask layer is made of a light sensitive material.

In accordance with the abovementioned method, the metal grid is formed by printing.

In accordance with the abovementioned method, a backside metal is formed as an anode of the solar cell on the silicon substrate at a side opposite to the emitter layer.

In accordance with another aspect of the present invention, a method of manufacturing a selective emitter of a solar cell is provided. The method includes the following steps: providing a P-type silicon substrate; forming an N-type silicon layer on the P-type silicon substrate; forming a mask layer on the N-type silicon layer to have a grid line area; performing a wet etching preserving the grid line area; and forming a metal layer on the grid line area.

Preferably, the N-type silicon layer comprises a lightly doped layer and a heavily doped layer.

Preferably, the wet etching is terminated when the lightly doped layer is exposed.

Preferably, the mask layer defines the grid line area on the heavily doped layer.

Preferably, a backside metal is formed as an anode of the solar cell on the P-type silicon substrate at a side opposite to the emitter layer.

The above objects and advantages of the present invention will become more readily apparent to those ordinarily skilled in the art after reading the details set forth in the descriptions and drawings that follow, in which:

### BRIEF DESCRIPTION OF THE DRAWINGS

FIG. 1 is a schematic diagram showing the procedure of making a selective emitter of a solar cell in the prior art; and

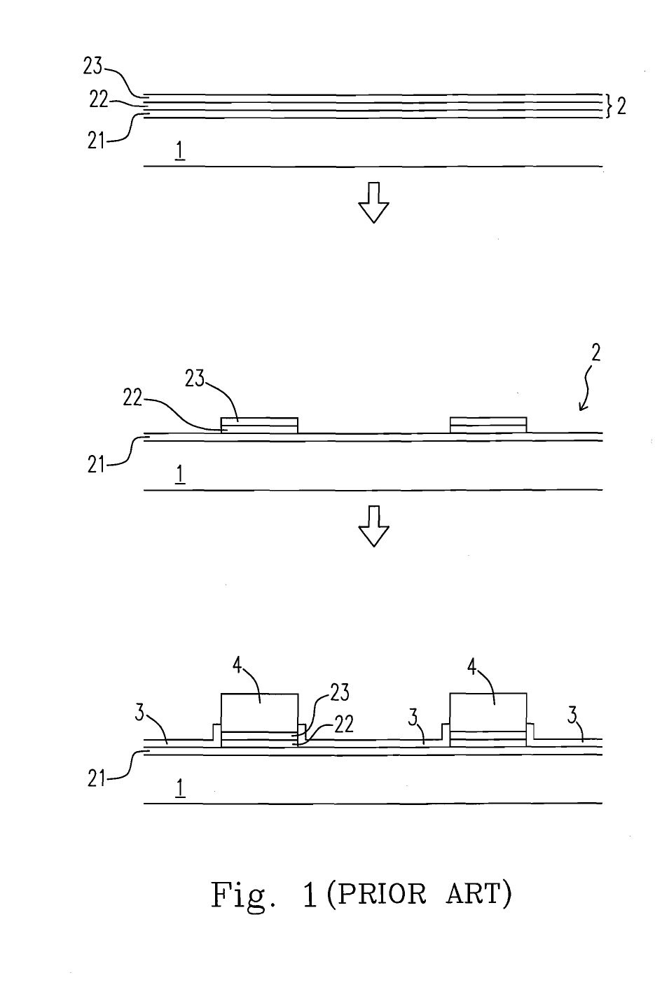

FIG. 2 is a schematic diagram showing the procedure of making a selective emitter of a solar cell according to a preferred embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for the purposes of illustration and description only; it is not intended to be exhaustive or to be limited to the precise form disclosed.

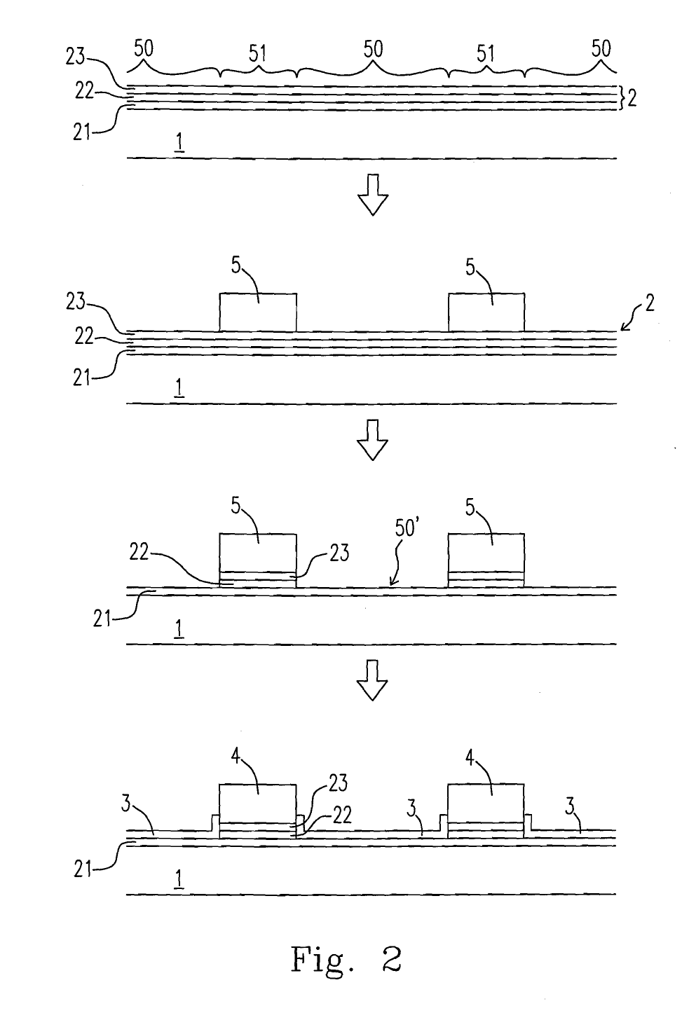

FIG. 2 is a schematic diagram showing the procedure of making a selective emitter of a solar cell according to a preferred embodiment of the present invention. The procedure may be briefly divided into the following steps.

Firstly, a silicon substrate 1 is provided (step 1). The silicon substrate 1 is P-type silicon, in accordance with the n-p silicon crystal solar cell. Then, an emitter layer (N-type silicon layer) 2 is formed on the silicon substrate 1 (step 2), wherein a heavily doped portion is located on top of the emitter layer 2 and a lightly doped portion is located next to the bottom of the heavily doped portion.

In step 2, one of the methods for achieving the difference of high and low doping concentration is to firstly form a first N-type silicon layer 21 on the silicon substrate 1. And then a second N-type silicon layer 22 and a third N-type silicon layer 23 are formed on the first N-type silicon layer 21 in sequence. With respect to the relative doping concentration of the three layers, the first N-type silicon layer 21 has the lowest density, the second N-type silicon layer 22 has more, and the third N-type silicon layer 23 has the highest density.

As mentioned hereinbefore, the heavily doped N-type silicon is for coupling to the grid metal lines. So the third N-type silicon layer 23 of the highest doping concentration is solely reserved for carrying the portion of the grid metal lines (not shown). The other portion is reserved for serving as active regions. And indeed the active regions require the lightly doped N-type silicon only. Therefore the middle area in FIG. 2 shows an area in which both the second N-type silicon layer 22 and the third N-type silicon layer 23 of the active region are removed. Consequently, a removing area 50 and a reserving area 51 are further defined at a top view of the N-type silicon layer 2, wherein the removing area 50 is the active region, i.e. to remove both the heavily doped third N-type silicon 23 and the averagely doped second N-type silicon 22. The area left after the removal may serve as the active region while the reserving area 51 takes on the grid metal line 4. It is to be clarified that only a portion of the so-called emitter layer 2 serves for the use of an emitter while the other portion active region. There has been no difference before the step 2, so the layer is named emitter layer.

Next, a patterned mask layer 5 is formed on top of the emitter layer 2 (step 3). Usually the mask layer 5 is made of an anti-corrosion material, such as wax, on the emitter layer 2 for defining a pattern. Relying on the mask layer 5, the areas including the third N-type silicon layer 23 and below can be protected from etching by corrosive liquid. And the pattern is exactly what the grid metal line 4 tends to be, and is the shape for the reserving area 51. The area excluding the pattern usually serves as the active region.

Afterwards, a wet etching is performed for exposing the lightly doped portion which is not covered by the mask layer 5 (step 4). In other words, the emitter layer 2 is etched with a liquid all the way to the lightly doped layer, wherein the lightly doped layer is the first N-type silicon layer 21, and the characteristic of light doping of the first N-type silicon layer 21 is exactly what the active region needs. Therefore, a selective emitter of a solar cell is produced, after completion of the reserving area and the active region.

Besides, the production method hereinbefore further includes the following steps: (a) removing the mask layer 5; (b) forming a nitric layer 3 at the surface of the lightly doped portion of the emitter layer 2; and (c) forming a metal grid 4 on the surface of the heavily doped portion of the emitter layer 2. The nitric layer 3 on the emitter layer 2 is located on top of the first N-type silicon layer 21, and the metal grid 4 is located on top of the third N-type silicon layer 23. In addition, the metal grid 4 can be formed by means of printing and its material may essentially be a good conductor for electricity such as gold, silver, copper, aluminum, etc.

Furthermore, a cleaning process is usually performed after the wet etching to the emitter layer 2, and the anti-corrosion material is removed afterwards. Such a removal process is performed after the above-mentioned step 4 and before the step of “forming a nitric layer 3 at the surface of the lightly doped portion of the emitter layer 2”.

Since this kind of production process for n-p silicon crystal solar cells is almost identical to that for semiconductors, some methods such as photolithograph may also be adopted for defining the pattern of the reserving area. Consequently, some photographic materials and photographic emulsions may be used for the anti-corrosion material of the mask layer 5. Therefore, the method provided by the present invention is able to build more compact solar cells.

Alternatively, the method for making a selective emitter of a solar cell in the present invention may be completed with the following steps: (a) providing a P-type silicon substrate 1; (b) forming an N-type silicon layer 2 on a surface of the P-type silicon substrate 1; (c) forming a mask layer 5 on top of the N-type silicon layer 2, wherein the area covered by the mask layer 5 is a grid line area 51 (i.e. the reserving area 51); (d) performing a wet etching while reserving the grid line area 51; and (e) forming a metal layer 4 on top of the grid line area 51. Therefore the metal layer 4 constitutes a selective emitter.

On the other hand, a method for making a selective emitter of a solar cell in the present invention may also be accomplished with the following steps. Firstly, a reserving area 51 and a removing area 50 are defined on an N-type silicon layer 2, wherein all of the N-type silicon layer 2 defined as the reserving area 51, from the third N-type silicon layer 23 and below, is reserved. The third N-type silicon 23 in the reserving area is for carrying a grid metal line 4, so it is also the grid line area. Subsequently, the N-type silicon layer 2 of the removing area 50 is removed by means of wet etching, to form a removed area 50′, which is located between the two reserving areas 51 and is the abovementioned action region. Next, a silicon nitride is formed on the reserving area 51 and the removed area 50′. Finally, a metal layer 4 is formed on top of the reserved area 51 for serving as a grid metal line, thereby completing the selective emitter of the solar cell.

Regarding the light doping and heavy doping, the contact portion of the N-type silicon layer to the P-type silicon layer 1 is a lightly doped layer (first N-type silicon layer 21), while a heavily doped layer (third N-type silicon layer 23) is at a side far from the P-type silicon layer 1.

In addition, the third N-type silicon layer 23 in the reserving area 51 is for carrying the grid metal lines. So the reserving area 51 can also be named the grid line area. As described before, an anti-corrosion material such as wax is utilized for covering the reserving area 51, to protect the reserving area 51 from etching by corrosive liquid. The anti-corrosion material can also serve for defining the pattern of the grid line area designed in the reserving area 51.

Of course, a backside metal is formed on the silicon substrate at the side opposite to the emitter layer (not shown, to sever as an anode of the solar cell. The backside metal is an inherent structure of solar cells and will not be further described here.

The reason for adopting wet etching to produce the selective emitters of solar cells is that wet etching is very easy to control. By changing an ingredient percentage of the etching fluid, one may control several variables such as the etching rate, the isotropic or anisotropic etching, etc. And in general the etching rate of wet etching is higher than that of dry etching. The heavily doped N-type silicon between two grid metal lines can be removed, according to the method provided by the present invention, which may also contribute to the improvement of the efficiency of a solar cell. Moreover, a very important advantage lies in that the wet etching process is easy to be introduced to the solar cell production line. For instance the facility for forming the anti-corrosion layer can be in line with the facility for forming the N-type silicon layer. There exists the advantage when photolithograph technique is adopted for defining the pattern of the emitter metal line with an anti-corrosion material. And the burden is very light for the current solar cell production lines. Even with some additional process steps, huge throughput along with the extremely high yield rate would surely pay for the increased time consuming and cost.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims that are to be accorded with the broadest interpretation so as to encompass all such modifications and similar structures.

What is claimed is:

1. A method for manufacturing a selective emitter of a solar cell, comprising steps of:
providing a silicon substrate;
forming an emitter layer on the silicon substrate, wherein the emitter layer has a heavily doped portion located on a top thereof and a relatively lightly doped portion located at a bottom thereof;
forming a mask layer being patterned on the emitter layer; and
performing a wet etching for exposing a region of the relatively lightly doped portion which is not covered by the mask layer.

2. A method as claimed in claim 1, further comprising steps of:
removing the mask layer;
forming a nitric layer on a first surface of the lightly doped portion of the emitter layer; and
forming a metal grid on a second surface of the heavily doped portion of the emitter layer.

3. A method as claimed in claim 1, wherein the patterned mask layer is made of a wax.

4. A method as claimed in claim 1, wherein the silicon substrate and the emitter layer form a P-N junction.

5. A method as claimed in claim 1, wherein the patterned mask layer is defined by a photolithography.

6. A method as claimed in claim 1, wherein the mask layer is made of a light sensitive material.

7. A method as claimed in claim 1, wherein the metal grid is formed by printing.

8. A method as claimed in claim 1, wherein a backside metal is formed as an anode of the solar cell on the silicon substrate at a side opposite to the emitter layer.

9. A method for manufacturing a selective emitter of a solar cell, comprising steps of:
providing a P-type silicon substrate;
forming an N-type silicon layer on the P-type silicon substrate;
forming a mask layer on the N-type silicon layer to have a grid line area;
performing a wet etching and preserving the grid line area; and
forming a metal layer on the grid line area.

10. A method as claimed in claim 9, wherein the N-type silicon layer comprises a lightly doped layer and a heavily doped layer.

11. A method as claimed in claim 10, wherein the wet etching is terminated when the lightly doped layer is exposed.

12. A method as claimed in claim 10, wherein the mask layer defines the grid line area on the heavily doped layer.

13. A method as claimed in claim 9, wherein a backside metal is formed as an anode of the solar cell on the P-type silicon substrate at a side opposite to the emitter layer.
